(19) United States
(12) Patent Application Publication
(10) Pub. No.: US 2011/0114372 A1
(43) Pub. Date: May 19, 2011

(54) PRINTED WIRING BOARD

(75) Inventors: Hisashi KATO, Ogaki-shi (JP); Ryo AOKI, Ogaki-shi (JP)

(73) Assignee: IBIDEN CO., LTD., Ogaki-shi (JP)

(21) Appl. No.: 12/904,334

(22) Filed: Oct. 14, 2010

Related U.S. Application Data
(60) Provisional application No. 61/256,716, filed on Oct. 30, 2009.

(51) Int. Cl. H05K 1/03

(52) U.S. Cl. 174/256

(57) ABSTRACT

A printed wiring board has an insulation layer having upper and lower surfaces, an upper-surface circuit formed on the upper surface of the insulation layer, a resin insulation layer formed on the upper surface of the insulation layer and the upper-surface circuit and having a via-conductor opening through the resin insulation layer, a conductive circuit formed on the resin insulation layer, and a via conductor formed in the opening. The resin insulation layer has first and second surfaces. The second surface of the resin insulation layer faces the upper surface of the insulation layer. The conductive circuit is formed on the first surface of the resin insulation layer. The via conductor is connecting the conductive circuit and the upper-surface circuit. The opening has an inner wall which has a diameter decreasing from the second surface of the resin insulation layer toward the first surface of the resin insulation layer.

### CROSS-REFERENCE TO RELATED APPLICATIONS

The present application claims the benefits of priority to U.S. application Ser. No. 61/256,716, filed Oct. 30, 2009. The contents of that application are incorporated herein by reference in their entirety.

### BACKGROUND OF THE INVENTION

1. Field of the Invention

The present invention relates to a printed wiring board having a resin insulation layer and a via conductor.

2. Discussion of the Background

A via conductor is shown in FIG. 1 of Japanese Laid-Open Patent Publication 2007-273896. The via conductor shown in FIG. 1 of Japanese Laid-Open Patent Publication 2007-273896 tapers toward a conductive circuit on the core substrate. The contents of this publication are incorporated herein by reference in its entirety.

### SUMMARY OF THE INVENTION

According to one aspect of the present invention, a printed wiring board has an insulation layer having an upper surface and a lower surface on the opposite side of the upper surface, an upper-surface circuit formed on the upper surface of the insulation layer, a resin insulation layer formed on the upper surface of the insulation layer and on the upper-surface circuit and having a via-conductor opening through the resin insulation layer, a conductive circuit formed on the resin insulation layer, and a via conductor formed in the via-conductor opening. The resin insulation layer has a first surface and a second surface on the opposite side of the first surface of the resin insulation layer. The second surface of the resin insulation layer faces the upper surface of the insulation layer. The conductive circuit is formed on the first surface of the resin insulation layer. The via conductor is connecting the conductive circuit and the upper-surface circuit. The via-conductor opening in the resin insulation layer has an inner wall which has the diameter decreasing from the second surface of the resin insulation layer toward the first surface of the resin insulation layer.

According to another aspect of the present invention, a printed wiring board has a core substrate having an upper surface and a lower surface on the opposite side of the upper surface, the core substrate having a penetrating hole, a through-hole conductor formed in the penetrating hole of the core substrate, an upper-surface circuit formed on the upper surface of the core substrate, a coating circuit covering the through-hole conductor, a resin insulation layer formed on the upper surface of the core substrate, the upper-surface circuit and the coating circuit, the resin insulation layer having a first opening exposing the coating circuit and a second opening exposing the upper-surface circuit, multiple conductive circuits formed on the first surface of the resin insulation layer, and via conductors formed on the inner walls of the first opening and the second opening, respectively. The resin insulation layer has a first surface and a second surface on the opposite side of the first surface of the resin insulation layer. The second surface of the resin insulation layer faces the upper surface of the insulation layer. The via conductor formed in the first opening is connecting one or more of the conductive circuits and the coating circuit. The via conductor formed in the second opening is connecting one or more of the conductive circuits and the upper-surface circuit. The first opening in the resin insulation layer has the diameter which decreases from the second surface toward the first surface. The second opening in the resin insulation layer has the diameter which decreases from the first surface toward the second surface.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 are views showing steps for manufacturing a printed wiring board relating to the first embodiment of the present invention;

FIG. 2 are views showing steps for manufacturing a printed wiring board of the first embodiment;

FIG. 3 are views showing steps for manufacturing a printed wiring board of the first embodiment;

FIG. 4 are views showing steps for manufacturing a printed wiring board of the first embodiment;

FIG. 5 are views showing steps for manufacturing a printed wiring board of the first embodiment;

FIG. 6(A) is a cross-sectional view showing a magnified view of a via conductor in a printed wiring board relating to the first embodiment;

FIG. 6(B) is a plan view of a conductive circuit formed on the via conductor;

FIGS. 6(C) and 6(D) are views to illustrate how to form an opening in an interlayer resin insulation layer;

FIG. 7 are views to illustrate steps for forming an opening in the printed wiring board relating to the first embodiment;

FIG. 8(A) is a view to illustrate a laser apparatus used in a printed wiring board relating to the first modified example of the first embodiment;

FIGS. 8(B) and 8(C) are views to illustrate steps for forming openings in the printed wiring board;

FIG. 9 are views to illustrate steps for forming an opening in a printed wiring board relating to the second modified example of the first embodiment;

FIG. 10 are views showing steps for manufacturing a printed wiring board relating to the second embodiment of the present invention;

FIG. 11 is a cross-sectional view showing a printed wiring board of the second embodiment of the present invention;

FIG. 12 are views showing steps for manufacturing a printed wiring board relating to the third embodiment of the present invention;

FIG. 13 are views showing steps for manufacturing a printed wiring board relating to the fourth embodiment of the present invention;

FIG. 14 are views to illustrate printed wiring boards relating to the first embodiment of the present invention; and

FIG. 15 are views to illustrate a printed wiring board relating to a modified example of the second embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

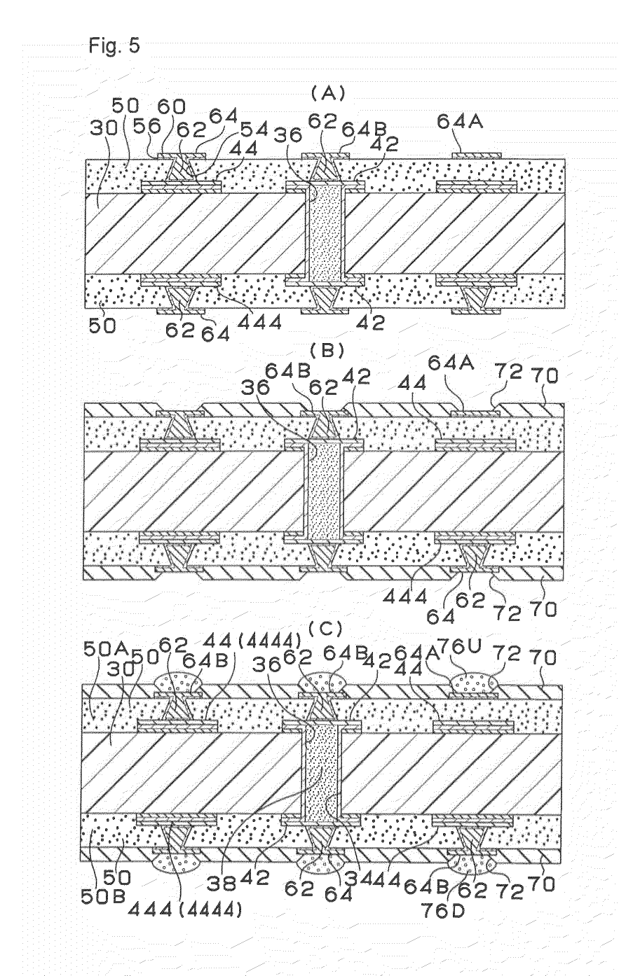

FIG. 5(C) is a cross-sectional view of a printed wiring board of the first embodiment. In printed wiring board 10, upper-surface circuits 44 are formed on the upper surface of core substrate 30, and lower-surface circuits 444 are formed on the lower surface. Conductive circuits (upper-surface circuits) 44 on the upper surface of core substrate 30 and conductive circuits (lower-surface circuits) 444 on the lower surface are connected by means of through-hole conductors 36 formed on the side walls of penetrating holes (penetrating holes for through-hole conductors) 34 in the core substrate. The shape of through-hole conductors in the first embodiment is cylindrical. Resin filler 38 is filled inside through-hole conductors 36. Resin filler 38 and through-hole conductors 36 are covered with coating circuits 42. Via conductors 62 are formed on coating circuits 42 or via-conductor pads 4444 which are part of conductive circuits (44, 444). Upper-layer interlayer resin insulation layer (50A) is formed on the upper surface of the core substrate and the upper-surface circuits, and lower-layer interlayer resin insulation layer (50B) is formed on the lower surface of the core substrate and the lower-surface circuits. Interlayer resin insulation layer (50A) has a first surface and a second surface opposite the first surface, and the second surface faces the upper surface of the core substrate. Interlayer resin insulation layer (50B) has a first surface and a second surface opposite the first surface, and the second surface faces the lower surface of the core substrate.

Circuits 64 are formed on interlayer resin insulation layers (50A, 50B). Circuits 64 contain conductive circuits (including signal conductive circuits, power-source conductive circuits and ground conductive circuits) (64A) and via-conductor lands (64B) formed surrounding via conductors. In addition, solder-resist layers 70 are formed on interlayer resin insulation layers (50A, 50B) and circuits 64. In solder-resist layers 70, openings 72 are formed partially exposing circuits 64. Circuits 64 exposed through openings 72 contain conductive circuits (64A), via-conductor lands (64B) and via conductors 62. Openings 72 may simultaneously expose the top surfaces of via conductors 62 and portions of lands (64B). Then, among circuits 64, the portions exposed through the openings work as solder pads. On solder pads, oxidation prevention film is formed, being made of an Ni layer and an Au layer (not shown in the drawings), for example. Solder bumps (76U, 76D) are formed on such oxidation prevention film.

Coating circuits 42 are connected to via-conductor lands (64B) and conductive circuits (64A) by means of via conductors 62 formed in interlayer resin insulation layers (50A, 50B). In the same manner, upper-surface circuits 44 on core substrate 30 are connected to via-conductor lands (64B) and conductive circuits (64A) by means of via conductors 62 formed in interlayer resin insulation layer (50A). Lower-surface circuits 444 on core substrate 30 are connected to via-conductor lands (64B) and conductive circuits (64A) by means of via conductors 62 formed in interlayer resin insulation layer (50B).

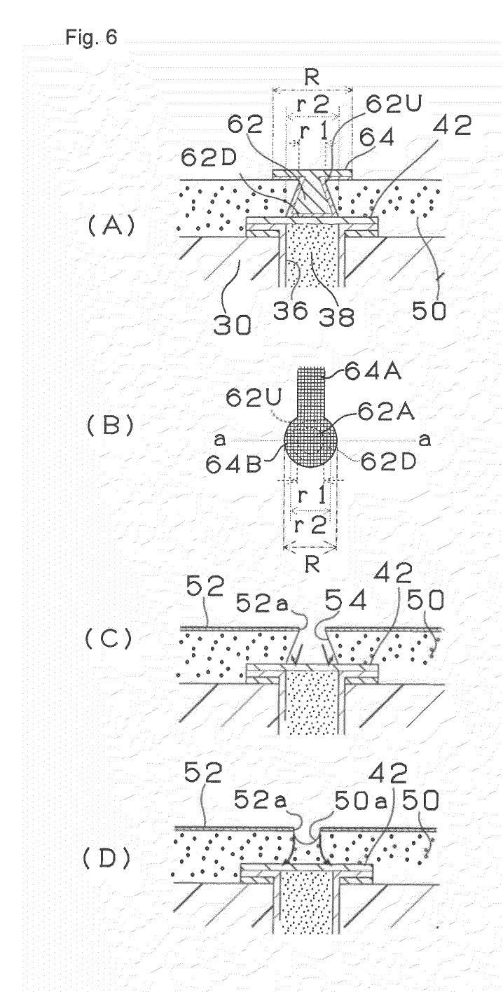

FIG. 5(A) shows a cross-sectional view of a printed wiring board having via conductors 62 and circuits 64. FIG. 6(A) shows a magnified view of a via conductor in FIG. 5(A). FIG. 6(B) is a plan view of FIG. 5(A) seen from the first-surface side of FIG. 5(A), showing top surface (62A) of a via conductor, via-conductor land (64B) contiguous to the via conductor, and conductive circuit (64A) connected to the via conductor. FIG. 6(A) corresponds to a cross-sectional view of FIG. 6(B) at the “a-a” line. In the first embodiment, via conductor 62 becomes wider from the first-surface side of the interlayer insulation layer toward the second surface side. Via-conductor opening 54 has top opening (62U) and bottom opening (62D). The top opening is an opening on the first surface of the interlayer resin insulation layer, and the bottom opening is an opening on the top surface of conductive circuit 44 or 444 on the core or on the top surface of a coating circuit. Diameter (r1) (55 μm) of top opening (62U) is relatively small, and diameter (r2) (65 μm) of bottom opening (62D) is relatively large. Here, conductive circuits (44, 444) on the core and the top surface of a coating circuit are the surfaces facing the second surface of interlayer resin insulation layers (50A, 50B). Therefore, the size of the bottom opening (the size of a via-conductor pad) is greater than the size of the top opening. Namely, connection reliability is seldom an issue in a printed wiring board of the present embodiment. The size of top opening (62U) is smaller, and the size of bottom opening (62D), which affects connection reliability, is larger. Thus, the connection size between a via conductor and a via-conductor pad becomes greater. Accordingly, connection reliability improves between a via conductor and a conductive circuit or between a via conductor and a coating circuit, leading to enhanced reliability of the printed wiring board. By setting diameter (r2) of bottom portion (62D) of via conductor 62 to be 30 μm or greater, connection reliability may be maintained. If (r2) is 60 μm or greater, connection reliability will not improve remarkably.

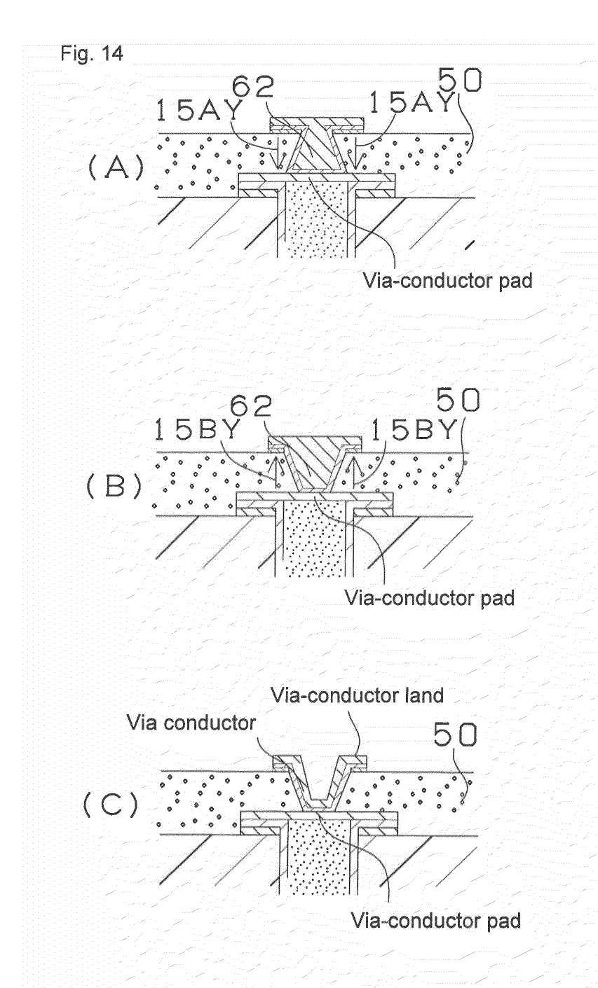

FIGS. 14(B) and 14(C) show configurations of via conductors in reference examples. FIG. 14(A) shows the configuration of a via conductor in the present embodiment. A via conductor in FIG. 14(B) becomes narrower from the first surface of the interlayer resin insulation layer toward the second surface. A via conductor in FIG. 14(A) becomes narrower from the second surface of the interlayer resin insulation layer toward the first surface. In addition, the directions of arrows (15AY, 15BY) in the drawings indicate the directions of force which the side walls of via conductors are thought to receive due to expansion of the interlayer resin insulation layers. Since the inclination of the side walls of via conductors is opposite in reference examples and the embodiment, it is thought that the direction of force which the side walls of via conductors receive due to expansion of interlayer resin insulation layers will be opposite. In the embodiment, it is thought that force acts in such a direction as to press a via conductor against the via conductor pad. In reference examples of FIGS. 14(B) and 14(C), it is thought that force acts in such a direction as to separate a via conductor from the via-conductor pad. When connection reliability is compared between a via conductor and the via-conductor pad in the embodiment and reference examples, the connection reliability in the embodiment is thought to be higher than that in the reference examples.

In the first embodiment, since resin filler 38 in through-hole conductor 36 has a greater thermal-expansion coefficient than core substrate 30 with a core material or the through-hole conductor, the coating circuit covering the resin filler will be pushed up by the thermal expansion of the resin filler. Therefore, during a heat cycle, it is thought that a great force will be exerted on the interface between via conductor 62 on coating circuit 42 and coating circuit 42, acting to separate them. As described above, since via conductor 62 in the first embodiment becomes gradually wider from the first surface of the interlayer resin insulation layer toward the second surface, the size of the portion connecting the bottom surface of a via conductor and the coating circuit will become greater. Accordingly, connection reliability improves between bottom portion (62D) of via conductor 62 and coating circuit 42, leading to enhanced reliability of the printed wiring board.

In the first embodiment, since diameter (r1) of top opening (62U) is smaller than the diameter of the bottom opening, diameter (R) of via-conductor land (64B) may be set smaller. Therefore, a printed wiring board being set smaller and having higher connection reliability may be obtained in the first embodiment.

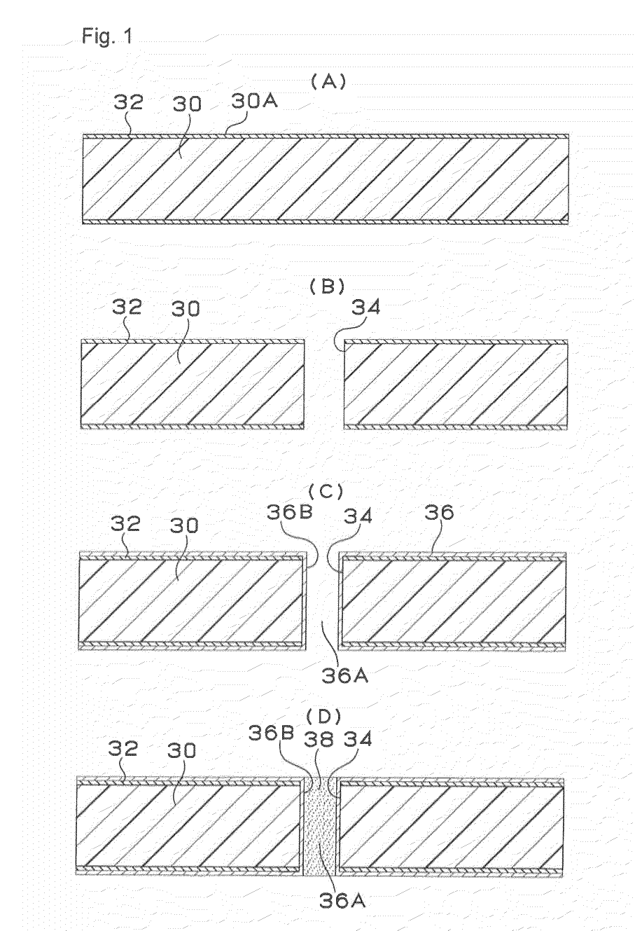

In the following, a method for manufacturing printed wiring board 10 described above with reference to FIG. 5(C) will be described by referring to FIGS. 1-7.

(1) Copper-clad laminate (30A) is prepared as a starting material, being made by laminating 5-250 μm-thick copper foil 32 on both surfaces of insulative substrate 30 made of 0.2-0.8 mm-thick glass-epoxy resin or BT (bismaleimide triazine) resin (FIG. 1(A)). Copper-clad laminate (30A) is preferred to have a core material such as glass cloth. First, penetrating hole 34 for a through-hole conductor (penetrating hole for through-hole conductor) is formed using a drill or a laser (FIG. 1(B)). Then, by conducting electroless plating treatment and electrolytic plating treatment, through-hole conductor (36B) is formed on the side wall of penetrating hole 34 (FIG. 1(C)). Simultaneously, conductive film 36 is formed on the copper foil, being made of electroless plated film and electrolytic plated film. In the first embodiment, as shown in FIG. 1(C), penetrating hole 34 is not filled with metal, and a printed wiring board of the first embodiment has penetrating hole (36A) in a through-hole conductor formed inside the through-hole conductor.

The surface of the through-hole conductor is roughened (not shown in the drawings).

(2) Next, resin filler 38 containing inorganic particles such as glass with an average particle diameter of 3-5 μm is filled in penetrating hole (36A) in the through-hole conductor, dried and cured (FIG. 1(D)).

Next, resin filler 38 bulging from penetrating hole (36A) in the through-hole conductor is removed by polishing so as to level out the surfaces of substrate 30 (not shown in the drawings). Penetrating hole (36A) in the through-hole conductor is filled with resin filler.

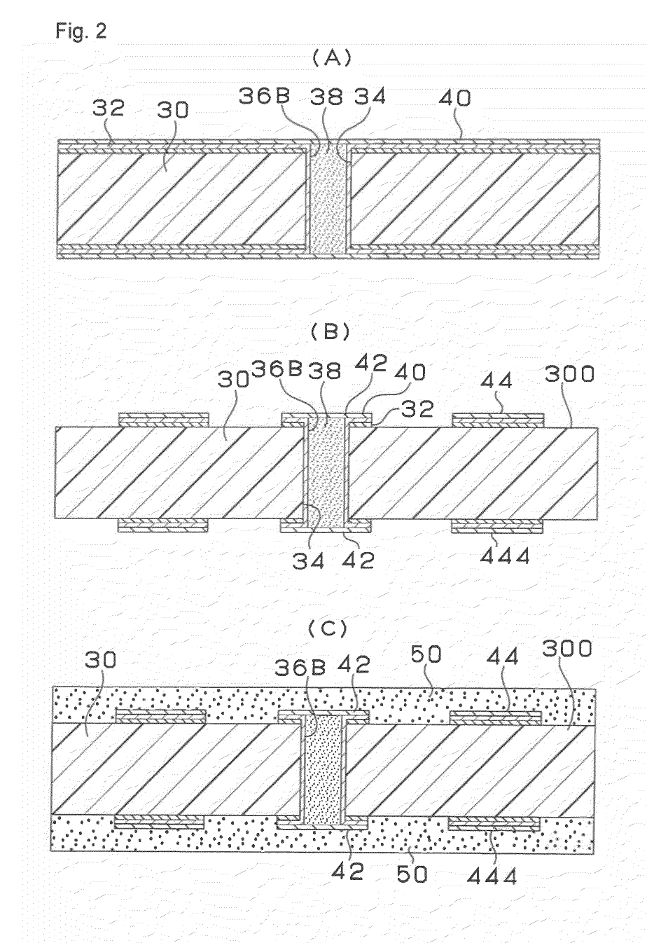

(3) After that, a palladium catalyst (made by Atotech) is applied on the surfaces of substrate 30 and electroless copper plating is performed to form 0.6 μm-thick electroless copper-plated film. Then, electrolytic copper plating is performed to form 15 μm-thick electrolytic copper-plated film. Plated film 40 is formed on copper foil 32, being made of electroless copper-plated film and electrolytic copper-plated film. At the same time, plated film 40 covers through-hole conductor 36 and resin filler 38 (FIG. 2(A)).

(4) A commercially available dry film is laminated on both surfaces of substrate 30 having plated film 40. After that, etching resist is formed on plated film 40 through photolithography. Then, plated film 40, conductive film 36 and copper foil 32 left exposed by the etching resist are resolved and removed by using an etching solution, and the etching resist is further removed. Upper-surface circuit 44, lower-surface circuit 444, and coating circuit 42, which covers filler 38 and through-hole conductor (36B), are formed (see FIG. 2(B)). Then, surfaces of upper-surface circuit 44, lower-surface circuit 444 and coating circuit 42 are roughened to form roughened surfaces (not shown in the drawings). Core substrate 300 is completed (FIG. 2(B)). The core substrate is the section through which a through-hole conductor penetrates.

(5) Resin film for interlayer resin insulation layers (brand name ABF-45SH, made by Ajinomoto) is laminated on both surfaces of core substrate 300. After that, by thermosetting the resin film for interlayer resin insulation layers at 170° C. for 40 minutes, interlayer resin insulation layer 50 is formed on both surfaces of core substrate 300. The side facing the core substrate is the second surface of an interlayer resin insulation layer, and the surface opposite the second surface is the first surface.

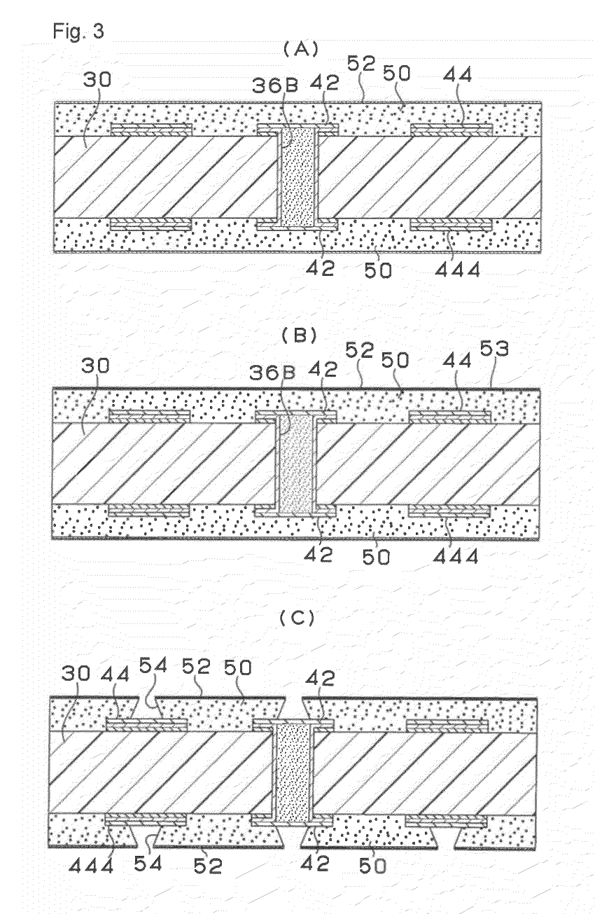

(6) Metal film 52 is formed on interlayer resin insulation layer 50 by electroless plating or sputtering (FIG. 3(A)).

(7) A black-oxide treatment is conducted on the surface of metal film 52, and black-oxide film 53 is formed on metal film 52 (FIG. 3(B)). With the formation of a black-oxide film, the metal film tends to absorb laser energy described later. It will be easier to form openings in the metal film by using a laser.

(8) Next, a CO₂-gas laser is beamed on the metal film. The number of pulses to be beamed is two. Via-hole opening 54 is formed in interlayer resin insulation layer 50 (FIG. 3(C)).

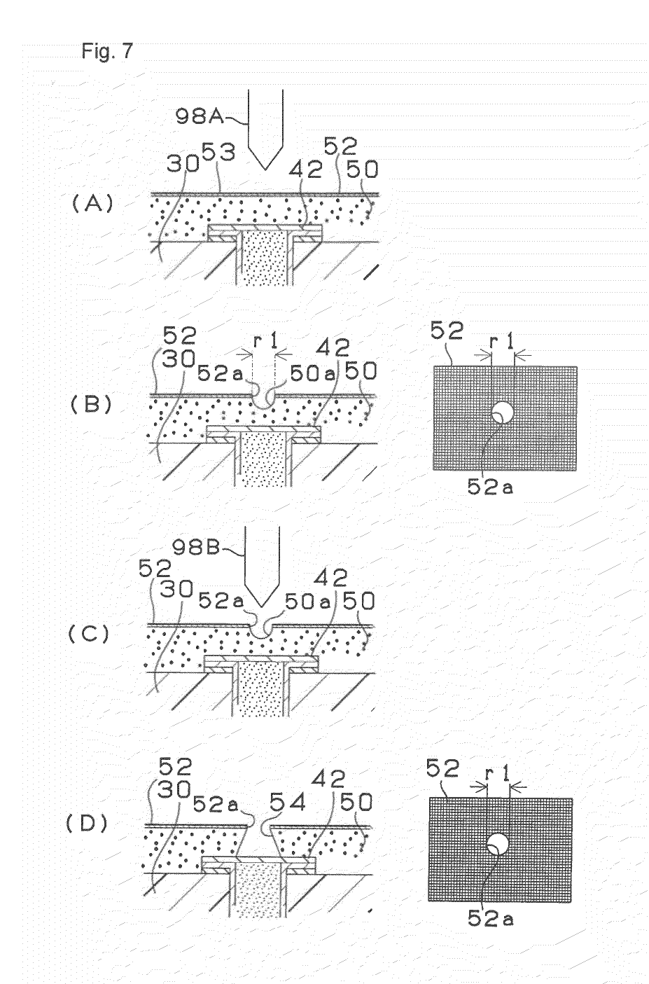

Opening 54 is formed in such a way that the lower-side diameter (bottom diameter) is set greater. Such a method is described in further detail with reference to FIG. 7. The energy of the first-pulse laser (98A) is adjusted to such a level that will penetrate through metal film 52 and will simultaneously remove part of interlayer resin insulation layer 50 (FIG. 7(A)). Accordingly, as shown in FIG. 7(B), opening (52a) with opening diameter (r1) (top diameter) is formed in metal film 52. At the same time, cavity (50a) is formed in interlayer resin insulation layer 50. On the right side of FIG. 7(B), a plan view of opening (52a) in metal film 30 is shown.

The energy of the second-pulse laser (98B) is preferred to be set at such a level that will not enlarge the diameter of opening (52a) in metal film 52, but will remove interlayer resin insulation layer 50 (FIG. 7(C)). As shown in FIG. 7(D), by the second-pulse laser beamed on the substrate having metal film 30, opening 54 is formed in interlayer resin insulation layer 50, becoming gradually wider from the upper-surface side (first surface) of the interlayer resin insulation layer toward the bottom-surface side (second surface). In other words, opening 54 gradually tapers from the second surface of the interlayer resin insulation layer toward the first surface.

On the right side of FIG. 7(D), a plan view of opening (52a) is shown. Since the energy of the second-pulse laser is set to be weak, the diameter of opening (52a) in metal film 52 will remain substantially the same. However, since the second-pulse laser may remove the interlayer resin insulation layer, an opening will be formed, reaching coating circuit 42 or conductive circuit 44 or 444. When the second-pulse laser reaches coating circuit 42 or conductive circuit 44 or 444, the laser will be reflected on the surface of coating circuit 42 or conductive circuit 44 or 444. Accordingly, the bottom-side diameter (bottom diameter) of opening 54 will tend to be enlarged as shown in FIG. 6(C). Therefore, in the first embodiment, opening 54 tends to become narrower from the second surface of the interlayer resin insulation layer toward the first surface. Moreover, since the energy of the second-pulse laser is at such a level that removing metal film 52 is difficult, the diameter of opening (52a) in metal film 52 will remain substantially the same. Then, by setting diameter (r1) of opening (52a) to be finer, such as 40-120 μm, the laser tends to be diffracted as shown in FIG. 6(D) after passing through opening (52a). Accordingly, the bottom diameter of opening 54 tends to become greater than the top diameter. Thus, opening 54 may be formed in reverse taper.

In the following, a method for manufacturing a printed wiring board is described. Metal film 52 is removed by etching. After that, by immersing a substrate having via-hole opening 54 in an 80° C. solution containing 60 g/l permanganic acid for 10 minutes, the surface of interlayer resin insulation layer 50 including the inner wall of via-hole opening 54 is roughened (not shown in the drawings).

(9) The above substrate having roughened surfaces is washed with water after the substrate is immersed in a neutralizer (made by Shipley Co., LLC). In addition, catalyst nuclei are attached on the surface of interlayer resin insulation layer 50 including the inner wall of via-hole opening 54.

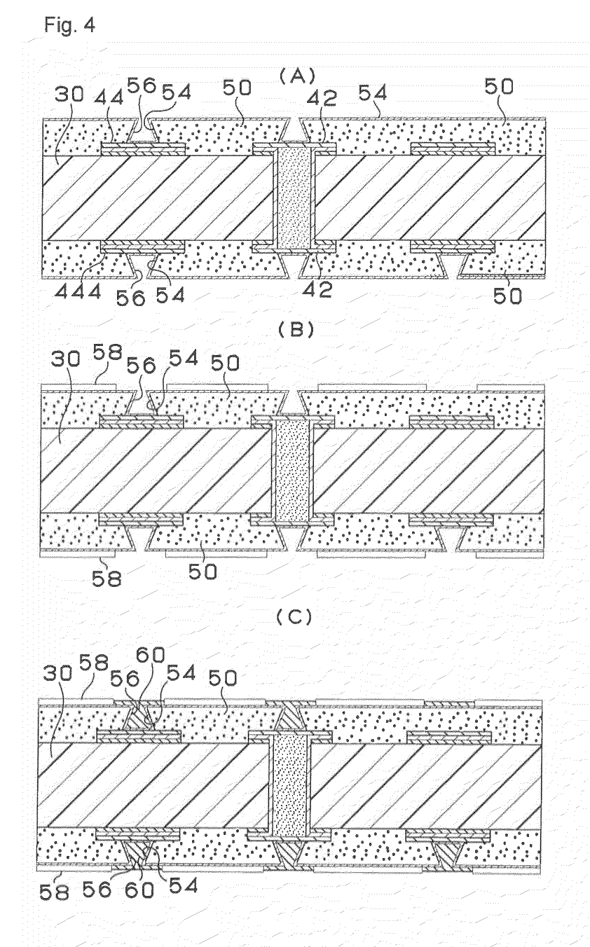

By immersing the substrate having the catalyst in an electroless copper plating solution (Thru-Cup PEA) made by C. Uyemura & Co., Ltd., electroless copper-plated film 56 is formed on the surface of interlayer resin insulation layer 50 including the inner wall of via-hole opening 54 (FIG. 4(A)).

(10) Next, plating resist 58 is formed on electroless copper-plated film 56 (FIG. 4(B)).

(11) Next, electrolytic copper-plated film 60 is formed on electroless copper-plated film 56 left exposed by the plating resist (FIG. 4(C)).

(12) Plating resist 54 is removed by using a 5%-KOH solution. After that, electroless plated film left exposed by the electrolytic plated film is dissolved and removed by a mixed solution of sulfuric acid and hydrogen peroxide. Accordingly, independent conductive circuit 64 and via conductor 62 are formed (FIG. 5(A)). Then, an oxidation-reduction treatment is conducted, and the surface of conductive circuit 64 is roughened (not shown in the drawings).

(13) Next, a solder-resist layer having openings 72 is formed on interlayer resin insulation layer 50 and conductive circuit 64 (FIG. 5(B)). Conductive circuits 64 and via conductors 62 exposed through openings 72 work as solder pads.

Next, a nickel layer and a gold layer are formed on solder pads (not shown in the drawings).

(14) After that, by forming solder bumps on solder pads, a printed wiring board with solder bumps (76U, 76D) is completed (FIG. 5(C)).

### First Modified Example of the First Embodiment

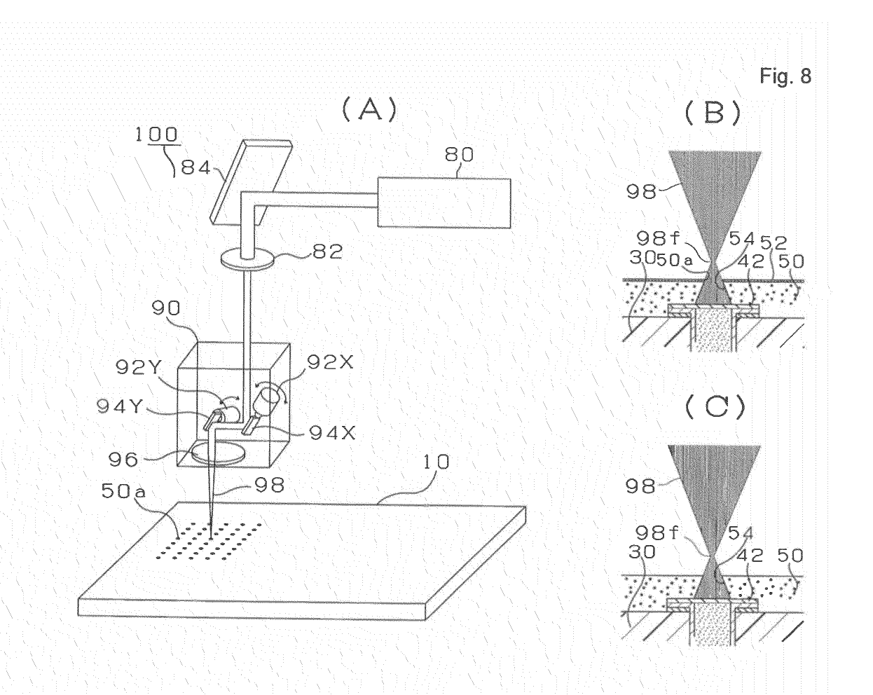

In the first embodiment described above, a reverse-taper opening is formed in an interlayer resin insulation layer by adjusting the laser energy. A reverse-taper opening indicates, for example, that the inner wall of an opening gradually tapers from the second surface of the interlayer resin insulation layer toward the first surface as shown in FIG. 3(C). In the first modified example of the first embodiment, a reverse-taper opening is formed in an interlayer resin insulation layer by adjusting the focal point of the laser. FIG. 8(A) shows the structure of laser apparatus 100. CO₂ laser oscillator 80 is used as a laser source.

Laser beams are scanned in X-Y directions by two galvanometer mirrors (94X, 94Y), pass through f-θ lens 96, and are beamed on an interlayer resin insulation layer of printed wiring board 10.

FIG. 8(B) is a view illustrating condensation of laser light by laser apparatus 100. By adjusting f-θ lens 96, focal point (98f) of laser 98 is positioned above metal film 52. Laser light converges before reaching metal film 52, and then diverges (FIG. 8(B)). Thus, the extent of the laser beamed on the first surface of an interlayer resin insulation layer is smaller than the extent of the laser beamed on the second surface of the interlayer resin insulation layer. Accordingly, in the first modified example, reverse-taper opening 54 is formed in an interlayer resin insulation layer.

### Second Modified Example of the First Embodiment

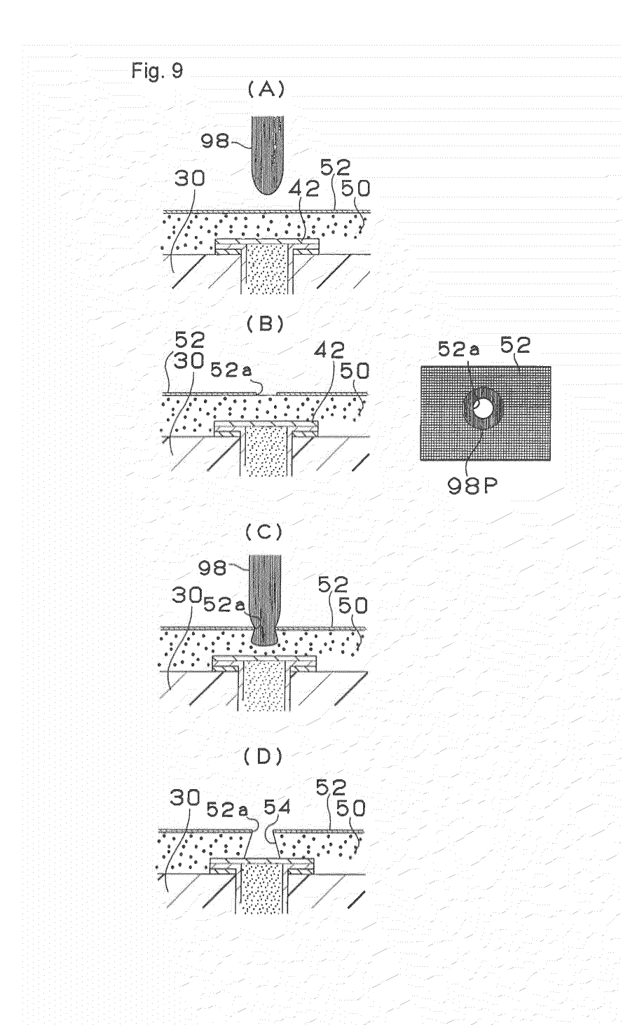

Forming an opening according to the second modified example of the first embodiment is described with reference to FIG. 9. FIG. 9(A) shows laser 98. FIG. 9(A) schematically shows laser intensity; the energy at the center is set stronger than the energy on the periphery. By beaming such a laser on metal film 52, reverse-taper opening 54 may be formed in an interlayer resin insulation layer (FIG. 9(D)). In the second modified example, since the laser energy is intense at the center, metal film 50 is removed at the center of the laser, forming opening (52a) in the metal film. On the right side of FIG. 9(B), a plan view of metal film 52 is shown. Laser is beamed on areas of metal film 52 outside opening (52a). However, since the laser energy beamed on such areas is weak, no opening is formed in the metal film. Then, as shown in FIG. 9(C), the laser passing through opening (52a) and beamed on the interlayer resin insulation layer diverges due to diffraction phenomena. Accordingly, as shown in FIG. 9(D), reverse-taper opening 54 is formed. The central energy of the laser used in the second modified example is set at such a level that removing metal film is possible, and the peripheral energy is set at such a level that removing metal film is difficult.

### Third Modified Example of the First Embodiment

In the first modified example of the first embodiment, a laser is beamed on metal film. However, in the third modified example, a laser is directly beamed on the first surface of an interlayer resin insulation layer. The same as in the first modified example, reverse-taper opening 54 is formed in the interlayer resin insulation layer (FIG. 8(C)). Methods for forming a reverse-taper opening in an interlayer resin insulation layer are described in the above modified examples. Such methods may be used in each of the embodiments.

### Second Embodiment

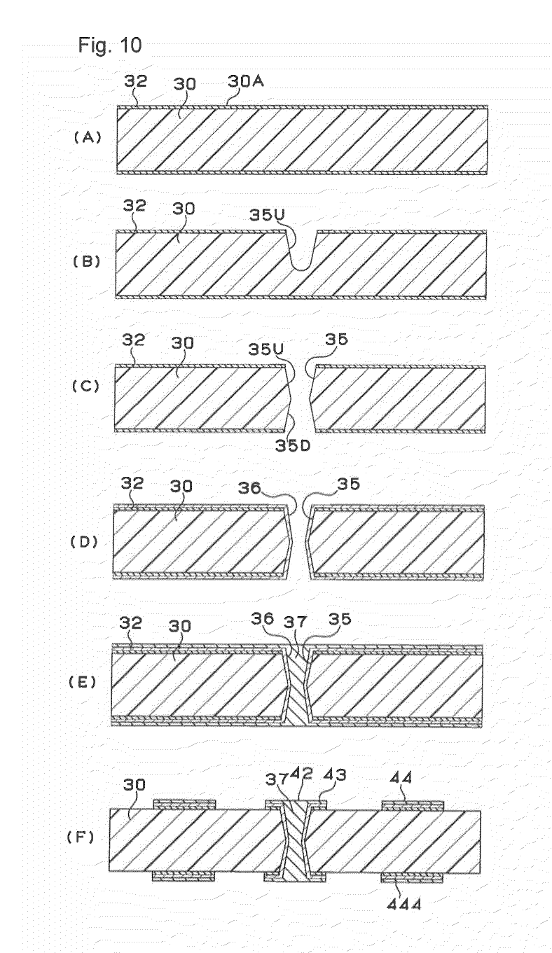

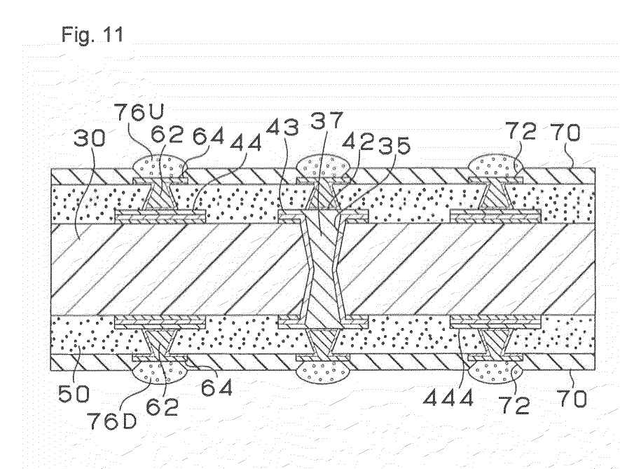

A printed wiring board relating to the second embodiment of the present invention is described with reference to FIGS. 10 and 11. FIG. 11 shows a cross-sectional view of a printed wiring board of the second embodiment. In the first embodiment, through-hole conductor 36 formed in core substrate 30 is in a cylindrical shape, and resin 38 is filled in through-hole conductor 36. By contrast, through-hole conductor 37 of the second embodiment is a conductor made by filling a penetrating hole for a through-hole conductor with plating.

The steps for manufacturing a core substrate of the second embodiment are described with reference to FIG. 10. Copper-clad laminate (30A) shown in FIG. 10(A) is prepared as a starting material. Copper-clad laminate (30A) has an upper surface (first surface) and a lower surface (second surface) opposite the upper surface. First, a laser is beamed on copper-clad laminate (30A) from the upper surface, and first opening portion (35U) is formed tapering from the upper surface toward the lower surface (FIG. 10(B)). Next, a laser is beamed from the lower surface, and second opening portion (35D) is formed tapering from the lower surface toward the upper surface. Accordingly, first opening portion (35U) and second opening portion (35D) are connected inside the core substrate, and penetrating hole 35 for a through-hole conductor is formed, being made up of first opening portion (35U) and second opening portion (35D) (FIG. 10(C)). A penetrating hole for a through-hole conductor in the second embodiment is a so-called hourglass-shaped penetrating hole, being made of a first opening portion tapering from the upper surface toward the lower surface and of a second opening portion tapering from the lower surface toward the upper surface. Next, electroless plated film 36 is formed inside penetrating hole 35 for a through-hole conductor and on the surfaces of the core substrate (FIG. 10(D)). Then, electrolytic plating is filled in penetrating hole 35 for a through-hole conductor (FIG. 10(E)). Through-hole conductor 37 is formed. Then, through-hole land 43, upper-surface circuit 44, lower-surface circuit 444 and coating circuit 42 are formed by patterning (FIG. 10(F)). A through-hole conductor is a portion that fills a penetrating hole for a through-hole conductor, and coating circuit 42 is a portion that is formed on the through-hole conductor. Through-hole land 43 is a portion on the copper-clad laminate and is contiguous to the coating circuit. Since the subsequent steps are the same as in the first embodiment, their descriptions are omitted.

In a printed wiring board of the second embodiment, an hourglass-shaped penetrating hole for a through-hole conductor is filled with metal plating. Thus, a printed wiring board of the second embodiment has hourglass-shaped through-hole conductor 37 made of metal plating. A through-hole conductor made of metal plating and core substrate 30 made of resin have remarkably different thermal expansion coefficients. Furthermore, since a through-hole conductor has an hourglass shape, stress may tend to be exerted between a via conductor formed on the top surface (exposed surface) of a through-hole conductor and the through-hole conductor. As the reason for such stress, it is assumed that due to the bent portion of a through-hole conductor of the second embodiment, the through-hole conductor tends to deform originating at the bent portion. However, in the second embodiment, since via conductor 62 is configured to become wider from the first surface of an interlayer resin insulation layer toward the second surface, the size of the portion connecting the via conductor and the coating circuit is greater. Accordingly, connection reliability is improved between via conductor 62 and through-hole land 43, leading to enhanced reliability of the printed wiring board.

### Modified Example of the Second Embodiment

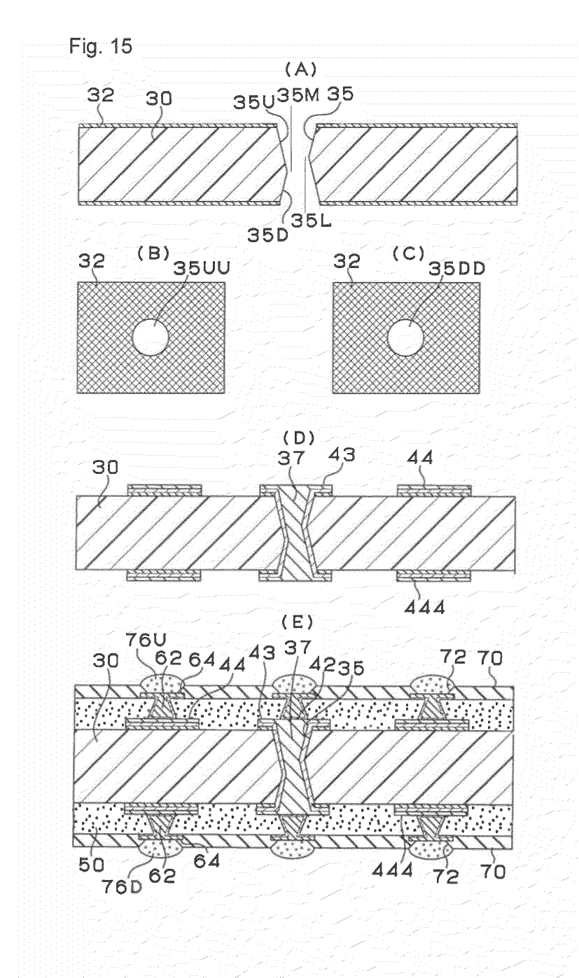

A cross-sectional view of a through-hole conductor in a modified example of the second embodiment is shown in FIG. 15(D). The through-hole conductor in FIG. 15(D) is made of a conductor filled in a penetrating hole for a through-hole conductor as shown in FIG. 15(A). The through-hole conductor in FIG. 15(D) is made of metal plating. Penetrating holes in the second embodiment and a modified example of the second embodiment are made up of first opening portion (35U) and second opening portion (35D). The first opening portion has first opening (35UU) on the first surface of the core substrate (FIG. 15(B)), and the second opening portion has second opening (35DD) on the second surface of the core substrate (FIG. 15(C)). Straight line (35M) is a straight line that passes through the gravity center of the first opening and is perpendicular to the first surface of the core substrate; straight line (35L) is a straight line that passes through the gravity center of the second opening and is perpendicular to the first surface of the core substrate (FIG. 15(A)). In the second embodiment, straight line (35M) corresponds to straight line (35L), and in the modified example, straight line (35M) is offset from straight line (35L). In the modified example, since the first opening portion and the second opening portion are offset, the size of the portion where the first opening portion and the second opening portion are connected tends to become smaller. As a result, stress generated between a through-hole conductor and a via conductor formed on the through-hole conductor tends to become greater. Therefore, in a printed wiring board having a through-hole conductor relating to the modified example of the second embodiment, via conductor 62 formed on coating circuit 42 is preferred to become wider from the first surface of the interlayer resin insulation layer toward the second surface (FIG. 15(E)).

### Third Embodiment

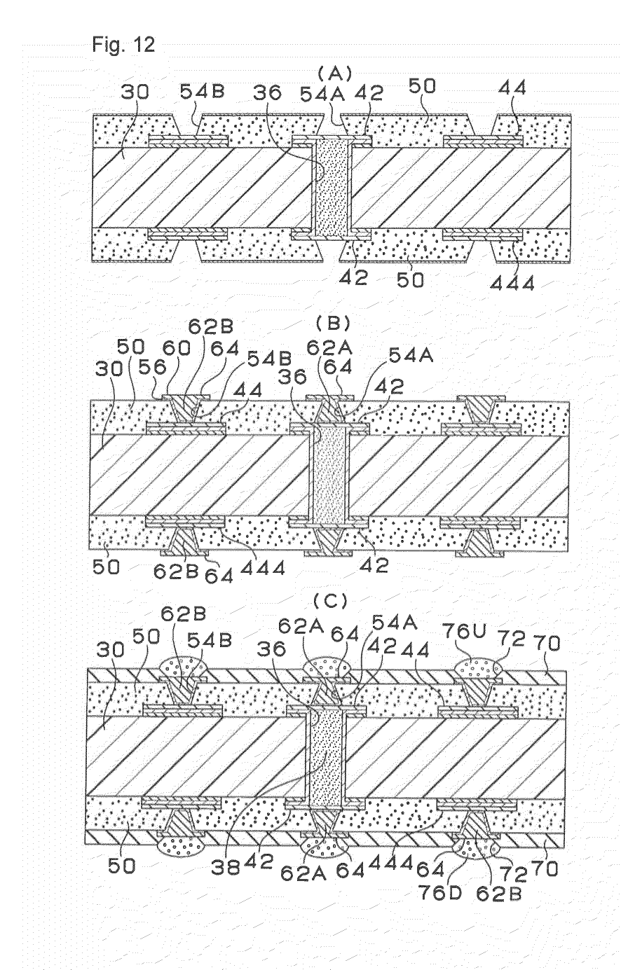

The third embodiment of the present invention is described with reference to FIG. 12. FIG. 12(C) shows a cross-sectional view of a printed wiring board in the third embodiment. Reverse-taper via conductor (62A) is formed on coating circuit 42 which covers resin filler 38 filling a penetrating hole in a through-hole conductor and the through-hole conductor. On upper-surface circuit 44 or lower-surface circuit 444 on the core substrate, via conductor (62B) is formed tapering from the first surface of an interlayer resin insulation layer toward the second surface.

Regarding the structure in the third embodiment, while enhancing the reliability of a printed wiring board by forming reverse-taper via conductor (62A) on coating circuit 42 where connection reliability is an issue, via conductor (62B) on upper-surface circuit 44 or lower-surface circuit 444 may be formed using a known method.

FIG. 12(A) shows via-conductor openings formed on coating circuits and conductive circuits (upper-surface circuits and lower-surface circuits). Via-conductor opening (54A) on coating circuit 42 is configured to be reverse-taper, and via-conductor opening (54B) on upper-surface circuit 44 or a lower-surface circuit is configured to taper from the first surface of an interlayer resin insulation layer toward the second surface. Reverse-taper opening (54A) may be formed by the same method as in the first embodiment. Via-conductor opening (54B) on upper-surface circuit 44 or the lower-surface circuit may be formed in the same method as in Patent Publication (1). Then, reverse-taper via conductor (62A) and standard-taper via conductor (62B) are formed through electroless plating and electrolytic plating (FIG. 12(B)). Standard-taper via conductor (62B) becomes narrower from the first surface of an interlayer resin insulation layer toward the second surface.

### Fourth Embodiment

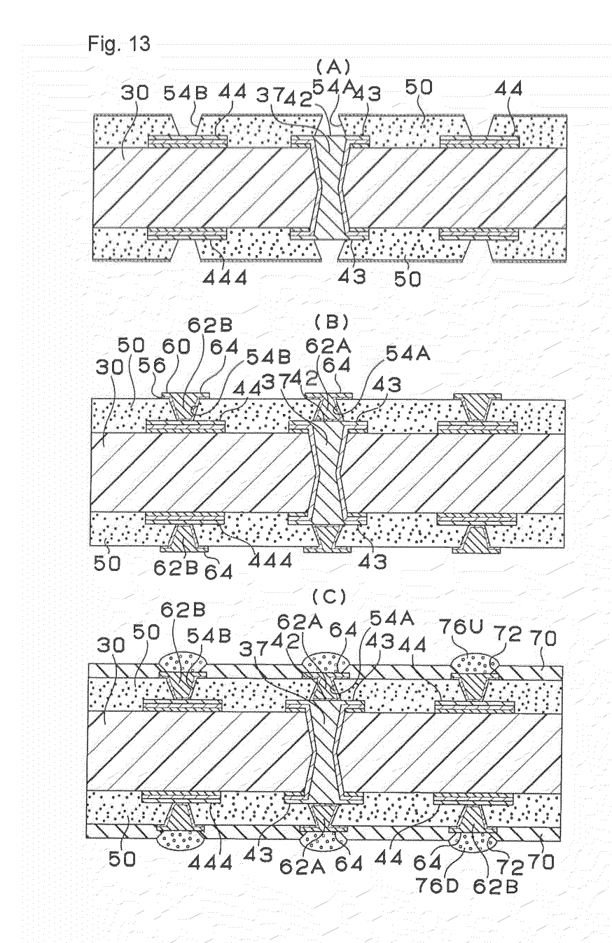

The fourth embodiment of the present invention is described with reference to FIG. 13. FIG. 13(C) shows a cross-sectional view of a printed wiring board in the fourth embodiment. Reverse-taper via conductor (62A) is formed on coating circuit 42 positioned on through-hole conductor 37, which fills a penetrating hole for a through-hole conductor with plating. Standard-taper via conductor (62B) is formed on upper-surface circuit 44 or lower-surface circuit 444 on the core substrate.

Regarding the structure in the fourth embodiment, while enhancing the reliability of a printed wiring board by forming reverse-taper via conductor (62A) on coating circuit 42 where connection reliability is an issue, via conductor (62B) on upper-surface circuit 44 or lower-surface circuit 444 may be formed using a known method.

FIG. 13(A) shows via-conductor openings formed on through-hole conductors and conductive circuits (upper-surface circuits and lower-surface circuits). Opening (54A) on a through-hole conductor is configured to be reverse-taper, and may be formed by the same method as in the first embodiment. Opening (54B) on a conductive circuit (upper-surface circuit or lower-surface circuit) is configured to taper from the first surface of an interlayer resin insulation layer toward the second surface, and may be formed in the same method as in Patent Publication (1). Then, reverse-taper via conductor (62A) and standard-taper via conductor (62B) are formed through electroless plating and electrolytic plating (FIG. 13(B)).

In the above-described embodiments, examples are shown where a single-layer interlayer resin insulation layer is formed on a core substrate. However, in each embodiment, multiple-layer interlayer resin insulation layers may also be formed. Electrolytic plated film forming via conductors may also be formed using a sputtered film as a seed layer. However, since electrolytic plated film is filled in reverse-taper openings in the present embodiments, electroless plated film is preferred to be used as a seed layer.

A printed wiring board according to one aspect of the present invention is formed with the following: an insulation layer having an upper surface and a lower surface opposite the upper surface; an upper-surface circuit formed on the upper surface of the insulation layer; a resin insulation layer formed on the upper surface of the insulation layer and on the upper-surface circuit, and having a first surface and a second surface which is opposite the first surface and faces the upper surface of the insulation layer, along with having a via-conductor opening; a conductive circuit formed on the first surface of the resin insulation layer; and a via conductor formed in the opening. In such a printed wiring board, the via conductor connects the conductive circuit and the upper-surface circuit, and the diameter of the inner wall of the opening in the resin insulation layer decreases from the second surface toward the first surface.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
an insulation layer having an upper surface and a lower surface on an opposite side of the upper surface;
an upper-surface circuit formed on the upper surface of the insulation layer;
a resin insulation layer formed on the upper surface of the insulation layer and on the upper-surface circuit and having a via-conductor opening through the resin insulation layer;
a conductive circuit formed on the resin insulation layer; and
a via conductor formed in the via-conductor opening,
wherein the resin insulation layer has a first surface and a second surface on an opposite side of the first surface of the resin insulation layer, the second surface of the resin insulation layer faces the upper surface of the insulation layer, the conductive circuit is formed on the first surface of the resin insulation layer, the via conductor is connecting the conductive circuit and the upper-surface circuit, and the via-conductor opening in the resin insulation layer has an inner wall which has a diameter decreasing from the second surface of the resin insulation layer toward the first surface of the resin insulation layer.

2. The printed wiring board according to claim 1, further comprising:
a penetrating hole formed in the insulation layer;
a through-hole conductor formed in the penetrating hole; and
a surface-coating circuit covering the through-hole conductor,
wherein the via-conductor opening exposes the surface-coating circuit.

3. The printed wiring board according to claim 2, wherein the through-hole conductor is formed on an inner wall of the penetrating hole, the through-hole conductor has a cylindrical shape, the through-hole conductor has a penetrating hole formed inside the through-hole conductor, the penetrating hole formed inside the through-hole conductor is filled with a resin filler, and the surface-coating circuit covers the through-hole conductor and the resin filler.

4. The printed wiring board according to claim 2, wherein the through-hole conductor is made of a metal filling the penetrating hole formed in the insulation layer.

5. The printed wiring board according to claim 4, wherein the penetrating hole formed in the insulation layer has a first opening portion and a second opening portion, the first opening portion of the penetrating hole is extending from the upper surface of the insulation layer and is tapering from the upper surface of the insulation layer toward the lower surface of the insulation layer, and the second opening portion of the penetrating hole is extending from the lower surface of the insulation layer and is tapering from the lower surface of the insulation layer toward the upper surface of the insulation layer.

6. A printed wiring board, comprising:
a core substrate having an upper surface and a lower surface on an opposite side of the upper surface, the core substrate having a penetrating hole;
a through-hole conductor formed in the penetrating hole of the core substrate;
an upper-surface circuit formed on the upper surface of the core substrate;
a coating circuit covering the through-hole conductor;
a resin insulation layer formed on the upper surface of the core substrate, the upper-surface circuit and the coating circuit, the resin insulation layer having a first opening exposing the coating circuit and a second opening exposing the upper-surface circuit;
a plurality of conductive circuits formed on the first surface of the resin insulation layer; and
a plurality of via conductors formed on inner walls of the first opening and the second opening, respectively,
wherein the resin insulation layer has a first surface and a second surface on an opposite side of the first surface of the resin insulation layer, the second surface of the resin insulation layer faces the upper surface of the insulation layer, the via conductor formed in the first opening is connecting at least one of the conductive circuits and the coating circuit, the via conductor formed in the second opening is connecting at least one of the conductive circuits and the upper-surface circuit, the first opening in the resin insulation layer has a diameter which decreases from the second surface toward the first surface, and the second opening in the resin insulation layer has a diameter which decreases from the first surface toward the second surface.

7. The printed wiring board according to claim 6, wherein the penetrating hole has a first opening portion and a second opening portion, the first opening portion of the penetrating hole is extending from the upper surface of the core substrate and is tapering from the upper surface of the core substrate toward the lower surface, the second opening portion of the penetrating hole is extending from the lower surface of the core substrate and is tapering from the lower surface of the core substrate toward the upper surface.

8. The printed wiring board according to claim 7, wherein the through-hole conductor is made of a metal filling the penetrating hole.
